(19) United States
(12) Patent Application Publication
(10) Pub. No.: US 2010/0244203 A1
(43) Pub. Date: Sep. 30, 2010

(54) SEMICONDUCTOR STRUCTURE HAVING A PROTECTIVE LAYER

(75) Inventor: Chantal Arena, Mesa, AZ (US)

Correspondence Address: TRASKBRITT, P.C., P.O. BOX 2550, SALT LAKE CITY, UT, 84110, US

(73) Assignee: S.O.I.TEC SILICON ON INSULATOR TECHNOLOGIES, Bernin (FR)

(21) Appl. No.: 12/678,978

(22) PCT Filed: Nov. 9, 2008
(86) PCT No.: PCT/IB2008/003038

§ 371 Date: May 28, 2010

Related U.S. Application Data
(60) Provisional application No. 60/988,260, filed on Nov. 15, 2007.

(51) Int. Cl. H01L 29/06; H01L 21/205

(52) U.S. Cl. 257/629; 438/478; 257/E21.101; 438/680; 257/E29.005

(57) ABSTRACT

A semiconductor structure includes a substrate having a first nitride-based semiconductor layer. A pseudomorphic protective layer is formed on the first nitride-based semiconductor layer and a second nitride-based semiconductor layer is formed on the pseudomorphic protective layer. The pseudomorphic protective layer has a thickness that is less than a critical thickness so that it drives the material quality of the second nitride-based semiconductor layer to correspond with that of the first nitride-based semiconductor layer.

### BACKGROUND OF THE INVENTION

1. Field of the Invention

This invention relates to the deposition of semiconductors on a substrate.

2. Description of the Related Art

Semiconductors are used to form a wide variety of solid-state devices. Some of these solid-state devices utilize semiconductor layers which include nitride-based semiconductors, such as gallium nitride (GaN), indium nitride (InN) and aluminum nitride (AlN), as well as their alloys. These nitride-based semiconductors are often referred to as the III-nitrides. It is desirable to form these semiconductor layers with a lower defect density and at a faster rate. Solid-state devices that include semiconductor layers having a lower defect density are useful because they are more likely to operate as desired and have a longer lifetime. Forming semiconductor layers at a faster rate is useful because the throughput is increased when forming solid-state devices on a number of different substrates. Further, forming semiconductor layers at a faster rate allows thicker layers to be formed in a given amount of time. The formation of thicker semiconductor layers is useful because the defect density is decreased, such as by defect annihilation.

Nitride-based semiconductors can be formed using many different growth techniques, such as metalorganic chemical vapor deposition (MOCVD), molecular beam epitaxy (MBE) and hydride (or halide) vapor phase epitaxy (HVPE), among others. More information regarding MOCVD and HVPE can be found in U.S. Patent Application Nos. 20060076559 and 20060118513, as well as in M. A. Mastro et al., “Influence of polarity on GaN thermal Stability”, Journal of Crystal Growth, Vol. 274, Pages 38-46 (2005) and M. A. Mastro et al., “Thermal stability of MOCVD and HVPE GaN layers in H₂, HCl, NH₃ and N₂”, Physica Status Solidi (a), Vol. 188, No. 1, Pages 467-471 (2001). It should be noted that the formation of a semiconductor is often referred to as deposition and growth.

A benefit of using MOCVD is the ability to nucleate III-nitride materials on native and non-native substrates. A native substrate includes a growth surface having a III-nitride material. A semiconductor layer with a high quality surface can be formed when the III-nitride material is nucleated effectively on the substrate. A high quality surface is generally smoother than a low quality surface. It is more difficult to nucleate III-nitride materials on native and non-native substrates using HVPE. Further, HVPE is known to form III-nitride materials having a lower quality surface. A low quality surface is generally rougher than a high quality surface.

However, MOCVD is impractical for forming thick layers of III-nitride materials because the growth rate is too slow. For example, the growth rate for growing III-nitride materials is typically in a range between about 1 to 3 microns per hour (μm/hour), so it can take between about 100 to 300 hours to form a III-nitride material layer having a thickness of about 300 μm. In comparison, HVPE is capable of forming III-nitride material layers at a rate between about 10 to 100 μm/hour or more, so a III-nitride material layer having a thickness of 300 μm can be formed in about 3 to 30 hours.

Hence, MOCVD grown semiconductor layers are useful because they have a higher quality surface than HVPE grown semiconductor layers. HVPE grown semiconductor layers are useful because they can be formed at a faster rate than MOCVD grown semiconductor layers. However, it is desirable to provide a growth technique which allows the formation, at a faster rate, of semiconductor layers having a higher quality surface.

### BRIEF SUMMARY OF THE INVENTION

The present invention employs a pseudomorphic protective layer formed on a first nitride-based semiconductor layer, and a second nitride-based semiconductor layer formed on the pseudomorphic protective layer. The pseudomorphic protective layer includes a semiconductor material that is more thermally and chemically stable than the material included in the first nitride-based semiconductor layer.

The thermal and chemical stability of the pseudomorphic protective layer preserves the material quality of the first nitride-based semiconductor layer when the second nitride-based semiconductor layer is formed. For example, the pseudomorphic protective layer reduces the amount of thermal and chemical induced material degradation experienced by the first nitride-based semiconductor layer when the second nitride-based semiconductor layer is formed.

The protective layer has a thickness below a critical thickness so it is pseudomorphic. The protective layer is pseudomorphic so that the material included therein has crystal properties which correspond with those of the material included in the first nitride-based semiconductor layer.

The second nitride-based semiconductor layer is formed on the pseudomorphic protective layer so that one or more of its crystal properties correspond with those of the pseudomorphic protective layer. Hence, the pseudomorphic protective layer drives the crystal properties of the first and second nitride-based semiconductor layers to correspond with each other. The second nitride-based semiconductor layer and pseudomorphic protective layers are blanket layers of material and the second nitride-based semiconductor layer has a thickness that is greater than the thickness of the pseudomorphic protective layer.

In one embodiment, the pseudomorphic protective layer and first nitride-based semiconductor layer are formed using different growth techniques. For example, the pseudomorphic protective layer and first nitride-based semiconductor layer can be formed using MOCVD, and the second nitride-based semiconductor layer can be formed using HVPE. In some embodiments, the MOCVD growth takes place heteroepitaxially on a non-native substrate, so that the optimized nucleation processes of the MOCVD growth technique can be employed for obtaining smooth III-nitride material layers. Further, the HVPE growth technique is utilized to enable high speed growth on the protective layer. In this way, the second nitride-based semiconductor layer is formed at a faster rate and has a lower defect density.

Further features and advantages of the invention will be apparent to those skilled in the art from the following detailed description, taken together with the accompanying drawings.

### BRIEF DESCRIPTION OF THE DRAWINGS

FIGS. 1a, 1b and 1c are side views of steps in fabricating a semiconductor structure, in accordance with the invention.

FIG. 2a is a perspective view of a template substrate which carries a pseudomorphic protective layer, wherein the template substrate and pseudomorphic protective layer are included in the semiconductor structure of FIGS. 1a, 1b and 1c.

FIG. 2b is a perspective view of the template substrate of FIG. 2a with a nitride-based semiconductor layer formed on the pseudomorphic protective layer.

FIGS. 3 and 4 are flow diagrams of methods of fabricating a semiconductor structure having a protective layer, in accordance with the invention.

### DETAILED-DESCRIPTION OF THE INVENTION

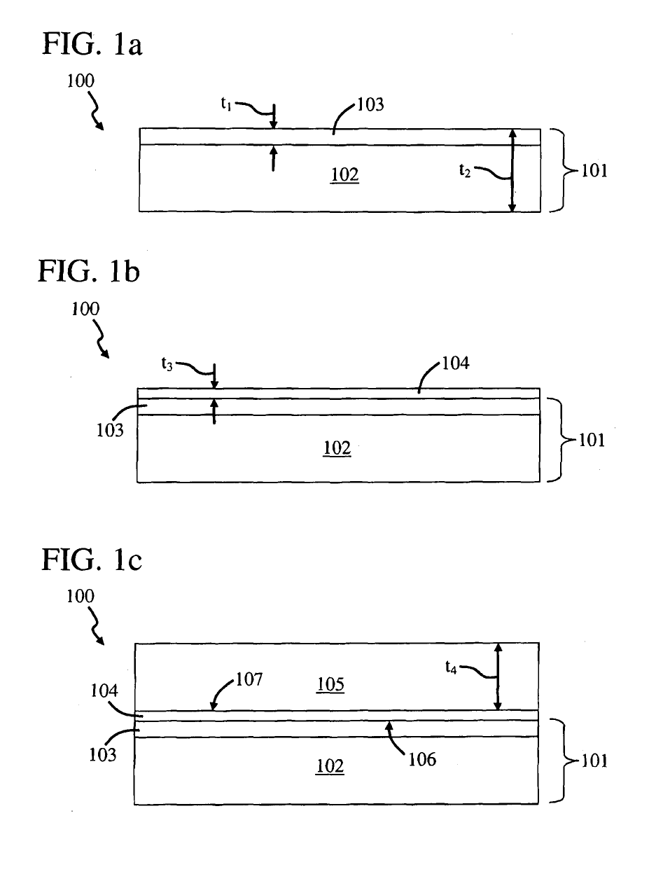

FIGS. 1a, 1b and 1c are side views of steps in fabricating a semiconductor structure 100, in accordance with the invention. In this embodiment, semiconductor structure 100 includes a template substrate 101, which is a composite substrate because it is non-homogenous. A composite substrate is non-homogenous when it includes two or more regions having different types of semiconductor materials. However, it should be noted that, in other embodiments, template substrate 101 can be replaced with a homogenous (e.g. free-standing) substrate which includes one region having the same type of semiconductor material.

In this embodiment, a region of template substrate 101 includes a support structure 102 and a different region of template substrate 101 includes a nitride-based semiconductor layer 103 (FIG. 1a). Support structure 102 can include many different types of materials. However, the materials included are typically chosen so that support structure 102 has crystal properties (e.g. crystal structure, lattice constants, coefficients of thermal expansion, etc.) that are similar to those of the material subsequently formed on template substrate 101.

It should be noted that support structure 102 can be a homogenous or non-homogenous support structure. A homogenous support structure includes one type of material, such as sapphire or silicon carbide (SiC), and a non-homogenous support structure includes two or more different types of materials, such as sapphire and silicon carbide. Examples of other materials that can be included in homogenous and non-homogenous support structures include silicon, silicon oxide, silicon nitride, gallium arsenide, lithium gallate and lithium aluminate, among others.

In this embodiment, a first material included in the non-homogenous support structure is chosen to have a desired coefficient of thermal expansion and a second material is chosen to have a desired crystal structure and lattice constants. For example, the first material can include silicon carbide and the second material can include sapphire so that support structure 102 has a sapphire-on-insulator-on-silicon carbide layer structure. The silicon carbide provides a desired coefficient of thermal expansion, which is chosen to reduce cracking of the material subsequently formed on template substrate 101 in response to cooling it from its growth temperature. The sapphire provides a material with a desired lattice structure and lattice constants which restrict the formation of defects in layers subsequently formed on template substrate 101. Examples of other layer structures that can be used in support structure 102 include sapphire-on-insulator-on-aluminum nitride, gallium nitride-on-insulator (GaNOI), silicon-on-polysilicon-carbide (SopSiC) and SiC on poly-crystalline SiC (SiCopSiC), among others.

Nitride-based semiconductor layer 103 can include many different types of nitride semiconductor materials, such as alloys of gallium nitride, indium nitride and aluminum nitride. However, in this embodiment, support structure 102 and nitride-based semiconductor layer 103 include sapphire and gallium nitride, respectively. It should be noted that when template substrate 101 is replaced with a homogeneous (e.g. free-standing) substrate, the material included therein can be of many different types, such as gallium nitride, indium nitride, aluminum nitride or an alloy thereof.

Nitride-based semiconductor layer 103 can be formed using many different growth techniques. However, the growth technique used to form nitride-based semiconductor layer 103 is chosen so that the material included therein has a desired material quality. The material quality can be determined in many different ways, such as by determining the material's defect density and crystal properties. The defect density and crystal properties can be determined using many different characterization techniques, such as Rutherford backscattering (RBS), transmission electron microscopy (TEM), atomic force microscopy (AFM) and x-ray diffraction (XRD).

The defects can be of many different types, such as impurities, grain boundaries, dislocations and vacancies. In general, a semiconductor material with a low defect density has a higher material quality than a semiconductor material with a high defect density. As mentioned above, the crystal properties of a material typically include its lattice structure, lattice constants and coefficient of thermal expansion. The lattice structure can be crystalline or non-crystalline. A crystalline lattice structure can be of many different types, such as hexagonal. In general, a semiconductor material with a crystalline lattice structure has a higher material quality than a semiconductor material with a non-crystalline lattice structure. It should be noted that a semiconductor material having a higher defect density and/or non-crystalline lattice structure has a degraded material quality.

In this embodiment, nitride-based semiconductor layer 103 is formed by positioning support structure 102 in an MOCVD reactor and depositing nitride-based semiconductor layer 103 on it by using MOCVD. MOCVD is used to form nitride-based semiconductor layer 103 for many different reasons, with one being that it is formed so it has a high material quality. MOCVD is also used to form nitride-based semiconductor layer 103 because it is known to provide a more fully optimized process for the nucleation of materials on support structure 102. The ability to nucleate materials on support structure 102 is useful because nitride-based semiconductor layer 103 can be formed so it has a high quality surface. Hence, MOCVD provides semiconductor layers with a smoother surface than those formed by using HVPE.

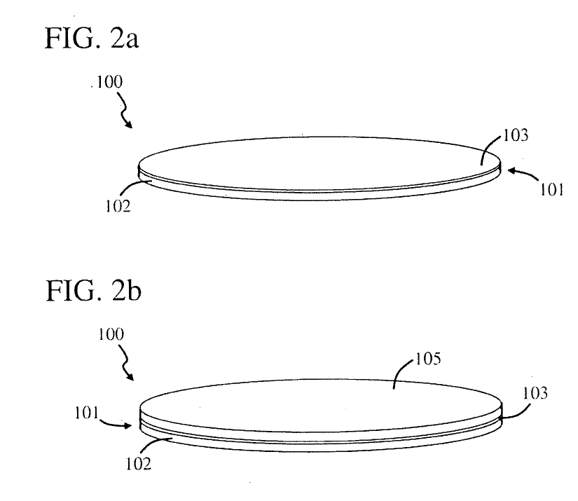

In accordance with the invention, semiconductor structure 100 includes a pseudomorphic protective layer 104 carried by template substrate 101 (FIG. 1b). Protective layer generally covers all or a desired portion of nitride-based semiconductor layer 103. It should be noted that pseudomorphic protective layer 104 is sometimes referred to as a capping layer, and is typically a blanket layer of material formed on template substrate 101. FIG. 2a is a perspective view of semiconductor structure 100, as shown in FIG. 1b, wherein pseudomorphic protective layer 104 is a blanket layer of material which covers nitride-based semiconductor layer 103.

It should be noted that nitride-based semiconductor layer 103 has a thickness t₁ and template substrate 101 has a thickness t₂, as shown in FIG. 1a. Further, pseudomorphic protective layer 103 has a thickness t₃, as shown in FIG. 1b. Thickness t₁ is greater than thickness t₃. Thickness t₁ can be greater than thickness t₃ by many different amounts. In one embodiment, thickness t₁ is more than about twice thickness t₃. In another embodiment, thickness t₁ is more than about an order of magnitude greater than thickness t₃.

In this embodiment, thickness t₃ extends from an interface of pseudomorphic protective layer 104 and nitride-based semiconductor layer 103 to an upper surface of protective layer 104. Thickness t₃ is shown as being constant across template substrate 101 for illustrative purposes. However, it should be noted that thickness t₃ generally varies across template substrate 101 so it is often not constant. However, all or a portion of pseudomorphic region 104 has a thickness that is less than the critical thickness.

When template substrate 101 is a free standing substrate, protective layers can be formed on opposed upper and lower sides of it. In this way, opposed upper and lower sides of the free standing substrate are covered with a protective layer. When protective layers are formed on opposed upper and lower sides of the free standing substrate, one or both of them can be pseudomorphic.

In accordance with the invention, pseudomorphic protective layer 104 includes a semiconductor material which is more thermally and chemically stable than the material included in nitride-based semiconductor layer 103. The material included in protective layer 104 is more thermally and chemically stable than the material included in nitride-based semiconductor layer 103 so that protective layer 104 protects nitride-based semiconductor layer 103 from having its material quality degraded.

The material quality of nitride-based semiconductor layer 103 can be degraded in many different ways, such as by exposing it to heat and/or chemicals. Nitride-based semiconductor layer 103 can be exposed to heat and chemicals in many different ways, one of which will be discussed in more detail with FIG. 1c. When nitride-based semiconductor layer 103 is exposed to heat and/or chemicals, it can experience damage inducing processes, such as dissociative sublimation and thermal decomposition, which degrade its material quality.

Hence, pseudomorphic protective layer 104 covers nitride-based semiconductor layer 103 so that nitride-based semiconductor layer 103 experiences less damage (e.g. by dissociative sublimation and thermal decomposition) when it is exposed to heat and/or chemicals. In this way, the degradation of the material quality of nitride-based semiconductor layer 103 is less likely to occur.

Pseudomorphic protective layer 104 allows nitride-based semiconductor layer 103 to be exposed to a temperature necessary for the formation of a nitride material layer on protective layer 104 with a reduced likelihood of it experiencing a degradation in its material quality. The types of chemicals that pseudomorphic protective layer 104 and nitride-based semiconductor layer 103 are exposed to can be in liquid and/or gaseous form and they generally include those chemicals used in semiconductor deposition. Examples of some chemicals used in semiconductor deposition include ammonia, hydrochloric acid, hydrogen, nitrogen, gallium chloride, Trimethylgallium, Trimethylindium and Trimethylaluminum, among others.

The thermal and chemical stability of a material, such as III-nitride-based semiconductor layer 103 and protective layer 104, can be determined in many different ways, such as with Atomic Force Microscopy (AFM), Auger Electron Spectroscopy (AES), Scanning Electron Microscopy (SEM) and Energy Dispersive X-ray Spectroscopy (EDS). More information regarding the thermal and chemical stability of a material can be found in M. A. Mastro et al., “Influence of polarity on GaN thermal Stability”, Journal of Crystal Growth, Vol. 274, Pages 38-46 (2005) and M. A. Mastro et al., “Thermal stability of MOCVD and HVPE GaN layers in H₂, HCl, NH₃ and N₂”, Physica Status Solidi (a), Vol. 188, No. 1, Pages 467-471 (2001).

Examples of materials that are suitable for use in pseudomorphic protective layer 104 include aluminum nitride, aluminum gallium nitride, boron nitride, boron carbide, silicon carbide, zinc oxide and tantalum nitride, among others. In this embodiment, however, protective layer 104 includes aluminum nitride. More information regarding aluminum nitride can be found in Jones et al., “A comparison of graphite and AlN caps used for annealing ion-implanted SiC”, Journal of Electronic Materials, OEM, Vol. 31, No. 6, Pgs. 568-575 (June 2002).

Aluminum nitride; aluminum gallium nitride, boron nitride, boron carbide, silicon carbide, zinc oxide and tantalum nitride are suitable for use in pseudomorphic protective layer 104 because they are more resistant to heat and chemicals than the material included in nitride-based semiconductor layer 103. It should be noted that aluminum nitride, aluminum gallium nitride, boron nitride, boron carbide, silicon carbide, zinc oxide and tantalum nitride can be formed so that one or more of their crystal properties correspond with the material included in nitride-based semiconductor layer 103.

Pseudomorphic protective layer 104 can be formed using many different growth techniques. However, in this embodiment, protective layer 104 is formed using the same growth technique as that used to form nitride-based semiconductor layer 103. Hence, protective layer 104 is formed using MOCVD when nitride-based semiconductor layer 103 is formed using MOCVD. Protective layer 104 and nitride-based semiconductor layer 103 are typically formed in the same MOCVD reactor. Hence, protective layer 104 can be formed on nitride-based semiconductor layer 103 without removing semiconductor structure 100 from the MOCVD reactor. In this way, protective layer 104 and nitride-based semiconductor layer 103 are formed in-situ. However, it should be noted that protective layer 104 can be formed ex-situ, if desired, wherein it is formed in a different reactor than nitride-based semiconductor layer 103.

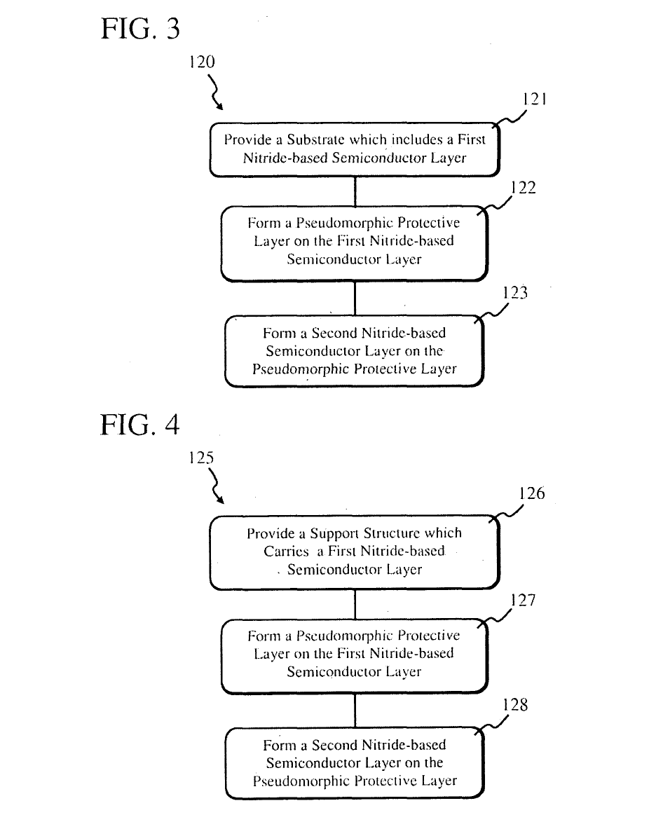

In addition, alternative ex-situ methods can be employed for the formation of protective layer 104, such as physical vapor deposition (PVD) methods like sputter deposition, evaporative deposition, pulsed laser deposition. Chemical vapor depositions methods, such as molecular beam epitaxy (MBE), atomic layer deposition (ALD) and plasma-enhanced chemical vapor deposition (PECVD), can also be used. It should, however, be appreciated that the methods outlined above should reduce the amount of degradation experienced by the material included in support structure 102 and nitride-based semiconductor layer 103. More information regarding the formation of a layer in-situ and ex-situ is provided with the discussion of FIG. 3.

Protective layer 104 can be formed in many different ways so it is pseudomorphic. In accordance with the invention, protective layer 104 is formed so its thickness t₃ is less than a critical thickness. The critical thickness of protective layer 104 is the thickness at which the strain in its lattice structure is relieved by the formation of defects, such as dislocations, so that the material is strain relaxed. Hence, thickness t₃ is chosen to restrict the formation of defects in pseudomorphic protective layer 104. In this way, the thickness of protective layer 104 is chosen so that layer 104 is pseudomorphic.

A limited amount of elastic strain can be accommodated by a semiconductor material without generating dislocations or defects. This accommodation of elastic strain requires an amount of elastic energy which is determined by the material thickness and amount of lattice mismatch between it and the layer it is formed on. Energy is also required to create a defect in the material to relieve the strain. Dislocations or defects can form if the strain energy is greater than this energy. Therefore, if the strain of the material included in pseudomorphic protective layer 104 is chosen so that the elastic energy remains below the energy of defect formation, the strained semiconductor layer will be stable against dislocation formation. This is called pseudomorphic growth since the growing epilayer maintains the lattice parameters of the underlying material. However, for a given material composition, strain increases with the thickness of the deposited material until a “critical thickness” is reached. When the thickness of the semiconductor material is greater than or equal to the critical thickness, the elastic strain in the material is sufficient to cause defect formation, which relieves the lattice strain.

The critical thickness of pseudomorphic protective layer 104 can have many different values, but it generally depends on the type of material included therein and the strain of its lattice structure. The critical thickness of pseudomorphic protective layer 104 also depends on the material that layer 104 is formed on. For example, when pseudomorphic protective layer 104 includes aluminum nitride, its critical thickness is generally in a range from about twenty angstroms to about sixty angstroms when nitride-based semiconductor layer 103 includes gallium nitride. In one example, the critical thickness is between about twenty-five angstroms to about forty angstroms when pseudomorphic protective layer 104 includes aluminum nitride and nitride-based semiconductor layer 103 includes gallium nitride. In another example, the critical thickness is between about forty angstroms to about fifty-five angstroms when pseudomorphic protective layer 104 includes aluminum nitride formed on gallium nitride. More information regarding the critical thickness of layers that include aluminum nitride can be found in Bykhovski et al. “Elastic strain relaxation in GaN—AlN—GaN semiconductor-insulator-semiconductor structures”, Journal of Applied Physics, Vol. 78, No. 6, Pg. 3691-3696 (1995) and Bourret et al. “Strain relaxation in (0001) AlN/GaN heterostructures”, Physical Review B-Condensed Matter, Vol. 63, Pg. 245307 (2001).

The critical thickness of pseudomorphic protective layer 104 can be adjusted in many different ways. For example, the critical thickness of pseudomorphic protective layer 104 can be adjusted by adjusting the composition of the material included therein. The composition of pseudomorphic protective layer 104 can be adjusted by adjusting the type and/or amounts of elements provided during its growth. For example, if pseudomorphic protective layer 104 includes a compound semiconductor material, the critical thickness is adjustable by adjusting the type and/or amounts of elements included in the growth gases.

If the material included in pseudomorphic protective layer 104 includes aluminum gallium nitride (AlXGa1-XN), the critical thickness can be adjusted by adjusting the amount of gallium and aluminum provided during its growth. The amount of gallium and aluminum provided during the growth of pseudomorphic protective layer 104 can be adjusted in many different ways. For example, a desired amount of aluminum can be included in the growth gas so that the desired composition of aluminum gallium nitride is formed.

In accordance with the invention, desired crystal properties of protective layer 104 correspond with those of nitride-based semiconductor layer 103 because layer 104 is a pseudomorphic layer. Hence, desired crystal properties of protective layer 104 correspond with those of nitride-based semiconductor layer 103 because its thickness is less than the critical thickness. The crystal properties of protective layer 104 and nitride-based semiconductor layer 103 can correspond with each other in many different ways.

In this embodiment, the material included in protective layer 104 and nitride-based semiconductor layer 103 have matching crystal structures. For example, the material included in pseudomorphic protective layer 104 has a hexagonal crystal structure when the material included in nitride-based semiconductor layer 103 has a hexagonal crystal structure. Hence, the crystal properties of protective layer 104 and nitride-based semiconductor layer 103 correspond with each other because they have matching crystal structures. It should be noted that aluminum nitride, aluminum gallium nitride, boron nitride, boron carbide, silicon carbide and tantalum nitride, as well as the alloys of indium aluminum gallium nitride, can be formed so they have hexagonal crystal structures.

The lattice constants of a material having a hexagonal crystal structure are generally denoted as a- (the in-plane lattice constant) and c-lattice constants. In this embodiment, the material included in pseudomorphic protective layer 104 and nitride-based semiconductor layer 103 have matching in-plane lattice constants (a-), wherein in-plane refers to planes parallel to that of the surface of the crystal. In-plane (a-) lattice constants of two layers are matching when they are the same or substantially the same so that the strain between the layers is not relaxed. Hence, the in-plane crystal structure of protective layer 104 and nitride-based semiconductor layer 103 correspond with each other because they have matching in-plane lattice constants.

The density of defects and dislocations included in protective layer 104 and nitride-based semiconductor layer 103 is reduced when the in-plane lattice constants of the materials included therein correspond with each other. Hence, preferred crystal properties of protective layer 104 and nitride-based semiconductor layer 103 correspond with each other because they have matching in-plane lattice constants. The in-plane lattice constants of the materials included in protective layer 104 and nitride-based semiconductor layer 103 can correspond with each other in many different ways.

In some embodiments, the a-lattice constants of the materials included in protective layer 104 and nitride-based semiconductor layer 103 are driven to match each other. The a-lattice constants of the materials included in protective layer 104 and nitride-based semiconductor layer 103 match each other when they are equal or substantially equal. The a-lattice constants of the materials included in protective layer 104 and nitride-based semiconductor layer 103 are substantially equal to each other when the strain between them is non-zero and the material included in protective layer 104 is not strain relaxed. In this way, the material included in protective layer 104 and nitride-based semiconductor layer 103 have corresponding in-plane lattice constants.

It should be noted that there is a lattice mismatch between the materials in protective layer 104 and nitride-based semiconductor layer 103 when the strain between them is non-zero. Further, it should be noted that the strain in pseudomorphic protective layer 104 can be tensile or compressive.

The critical thickness of pseudomorphic protective layer 104 is adjustable by adjusting its lattice mismatch with nitride-based semiconductor layer 103. In general, the critical thickness of pseudomorphic protective layer 104 decreases as the lattice mismatch between pseudomorphic protective layer 104 and nitride-based semiconductor layer 103 increases. Further, the critical thickness of pseudomorphic protective layer 104 increases as the lattice mismatch between pseudomorphic protective layer 104 and nitride-based semiconductor layer 103 decreases.

The lattice mismatch between pseudomorphic protective layer 104 and nitride-based semiconductor layer 103 can be adjusted in many different ways, such as by adjusting the growth parameters when forming protective layer 104. The lattice mismatch can also be adjusted by adjusting the composition of the material included in pseudomorphic protective layer 104 and/or nitride-based semiconductor layer 103.

In this embodiment, semiconductor structure 100 includes a nitride-based semiconductor layer 105 formed on protective layer 104 (FIG. 1c), wherein layer 105 has a thickness t₄. FIG. 2b is a perspective view of semiconductor structure 100, as shown in FIG. 1c, wherein nitride-based semiconductor layer 105 is a blanket layer of material which covers pseudomorphic protective layer 104.

Thickness t₄ can have many different values relative to thicknesses t₁, t₂ and t₃ (FIGS. 1a and 1b). In some embodiments, thickness t₄ is chosen to be greater than thickness t₁ of nitride-based semiconductor layer 103. In some embodiments, thickness t₄ is chosen to be greater than thickness t₂ of template substrate 101.

In this embodiment, thickness t₄ is chosen to be greater than thickness t₃ of pseudomorphic protective layer 104. Thickness t₄ can be greater than thickness t₃ by many different amounts. In one embodiment, thickness t₄ is more than about twice thickness t₃. In another embodiment, thickness t₄ is more than about one order of magnitude greater than thickness t₃. In another embodiment, thickness t₄ is more than about one to two orders of magnitude greater than thickness t₃.

The material included in nitride-based semiconductor layer 105 can be of many different types, such as an alloy of gallium nitride, indium nitride and aluminum nitride. However, in this embodiment, the material included in nitride-based semiconductor layer 105 is gallium nitride. It should be noted that one nitride-based semiconductor layer is shown as being included in nitride-based semiconductor layer 105. However, nitride-based semiconductor layer 105 may also comprise a heterostructure having two or more semiconductor layers, wherein one or more of them includes a nitride-based semiconductor material. The number of semiconductor layers included in nitride-based semiconductor layer 105 depends on the type of solid-state device it is desired to form therewith.

Nitride-based semiconductor layer 105 can be formed using many different growth techniques. However, in some embodiments the growth technique used to form nitride-based semiconductor layer 105 is chosen so that it is formed at a faster growth rate than nitride-based semiconductor layer 103 and protective layer 104. Hence, the growth techniques used to form first and second nitride-based semiconductor layers 103 and 105 in some embodiments are different. It should be appreciated, however, that in other embodiments nitride-based layers 103 and 105 are deposited using the same growth technique.

As mentioned above, a semiconductor material formed using HVPE generally has a growth rate that is more than about one to two orders of magnitude faster than the growth rate of a semiconductor material formed using MOCVD. A nitride-based semiconductor material formed using MOCVD typically has a growth rate in a range from about 1 μm per hour to about 3 μm per hour. A nitride-based semiconductor material formed using HVPE generally has a growth rate in a range from about 10 μm per hour to 100 μm per hour, or preferably 100 μm per hour to about 300 μM per hour.

In this embodiment, nitride-based semiconductor layer 105 is typically formed using HVPE by positioning template substrate 101, with protective layer 104 carried thereon, in an HVPE reactor and forming nitride-based semiconductor layer 105 on protective layer 104 by using HVPE. HVPE is used to form nitride-based semiconductor layer 105 because HVPE provides faster growth rates than those provided by MOCVD. Forming nitride-based semiconductor layer 105 at a faster growth rate is useful because the throughput is increased when forming solid-state devices on a number of different substrates.

When forming nitride-based semiconductor layer 105 with the HVPE growth technique, pseudomorphic protective layer 104 and nitride-based semiconductor layer 103 are typically exposed to chemicals, such as hydrochloric acid, hydrogen, ammonia, nitrogen, gallium chloride, ammonium chloride among others. However, as discussed in more detail above, pseudomorphic protective layer 104 includes a semiconductor material which is more thermally and chemically stable than the material included in nitride-based semiconductor layer 103. Hence, protective layer 104 protects nitride-based semiconductor layer 103 from having its material quality degraded in response to being exposed to heat and chemicals. Further, the material included in protective layer 104 is more thermally and chemically stable so that its material quality is not degraded in response to being exposed to heat and chemicals.

It is desirable to form the material included in nitride-based semiconductor layer 105 with HVPE so its material quality is driven to match or be better than that of nitride-based semiconductor layer 103. The material quality of nitride-based semiconductor layer 105 can be driven to match or be better than that of nitride-based semiconductor layer 103 in many different ways, several of which will be discussed in more detail presently. As mentioned above, the quality of a material generally corresponds with its defect density and crystal properties.

In accordance with the invention, the material included in nitride-based semiconductor layer 105 is formed with a low defect density by driving one or more of its crystal properties to correspond with those of protective layer 104. The crystal properties of protective layer 104 and nitride-based semiconductor layer 105 can correspond with each other in many different ways. In this embodiment, the materials included in protective layer 104 and nitride-based semiconductor layer 105 are chosen to have matching lattice structures. For example, the material included in nitride-based semiconductor layer 105 has a hexagonal lattice structure when the material included in protective layer 104 has a hexagonal lattice structure.

In this embodiment, the materials included in protective layer 104 and nitride-based semiconductor layer 105 are lattice matched so they have matching in-plane lattice constants. For example, the lattice structure of the material included in nitride-based semiconductor layer 105 can be strained so that its in-plane lattice constant matches that of the material included in pseudomorphic protective layer 104. It should be noted that the strain in the lattice structure of the material included in nitride-based semiconductor layer 105 can be tensile or compressive.

When the materials included in protective layer 104 and nitride-based semiconductor layer 105 have different lattice constants, they are lattice mismatched. However, the lattice mismatch between the material included in protective layer 104 and nitride-based semiconductor layer 105 is typically driven towards zero or below a desired threshold mismatch value. The lattice mismatch between protective layer 104 and nitride-based semiconductor layer 105 is driven below the desired threshold mismatch value so that layer 104 is not strain relaxed. The lattice mismatch between the material included in protective layer 104 and nitride-based semiconductor layer 105 can be driven towards zero or below the desired threshold mismatch value in many different ways, such as by adjusting the composition of layers 104 and 105.

When the material included in protective layer 104 and nitride-based semiconductor layer 105 have a hexagonal lattice structure, the lattice constants are generally denoted as the a- and c-lattice constants. Further, the a-lattice constant is often referred to as the in-plane lattice constant.

In accordance with the invention, the in-plane lattice constants of the materials included in pseudomorphic protective layer 104 and nitride-based semiconductor layer 105 correspond with each other. The in-plane lattice constants of the materials included in protective layer 104 and nitride-based semiconductor layer 105 can correspond with each other in many different ways. For example, in some embodiments, the a-lattice constants of the materials included in protective layer 104 and nitride-based semiconductor layer 105 are driven to match each other. The a-lattice constants of the materials included in protective layer 104 and nitride-based semiconductor layer 105 match each other when they are equal or substantially equal. The a-lattice constants of the materials included in protective layer 104 and nitride-based semiconductor layer 105 are substantially equal to each other when the strain between them is non-zero and the material included in protective layer 104 is not strain relaxed. In this way, the material included in protective layer 104 and nitride-based semiconductor layer 105 have corresponding in-plane lattice constants.

When the lattice structure and in-plane lattice constant of the material included in nitride-based semiconductor layer 105 are driven to correspond with those of the material included in pseudomorphic protective layer 104, the defect density of the material included in nitride-based semiconductor layer 105 is reduced. For example, the defect density of nitride-based semiconductor layer 105 is reduced when it has fewer dislocations extending through it. In this way, the crystal properties of the material included in nitride-based semiconductor layer 105 are chosen so that it has a low defect density.

It should be noted that the materials included in nitride-based semiconductor layer 103 and pseudomorphic protective layer 104 are latticed matched to reduce the defect density proximate to an interface 106 (FIG. 1c). Further, the materials included in III-nitride-based semiconductor layer 105 and pseudomorphic protective layer 104 are latticed matched to reduce the defect density proximate to an interface 107.

It should also be noted that nitride-based semiconductor layer 105 is typically processed to form one or more solid-state devices therewith. The solid-state devices include semiconductor layers having a low defect density because, as discussed above, nitride-based semiconductor layer 105 has a low defect density. Hence, the solid-state devices are more likely to have a longer lifetime and operate as desired.

In some embodiments, nitride-based semiconductor layer 105 is used to form one or more substrates by using a bonding and layer transfer process. More information regarding the bonding and layer transfer process, as well as other processes, can be found in U.S. Pat. Nos. 6,953,736, 6,908,828 and 6,815,309, the contents of which are incorporated herein by reference. More information can also be found in U.S. Patent Application Nos. 200660118513 and 20060099776, the contents of which are incorporated herein by reference.

FIG. 3 is a flow diagram of a method 120 of fabricating a semiconductor structure, in accordance with the invention. In this embodiment, method 120 includes a step 121 of providing a substrate which includes a first nitride-based semiconductor layer. It should be noted that the substrate can be a homogeneous or non-homogeneous substrate and the substrate can be provided to the user or it can be formed by the user. It should also be noted that the first nitride-semiconductor layer can be provided to the user with the substrate or it can be formed on the substrate by the user. The first nitride-based semiconductor layer can be formed using many different growth techniques. However, in this embodiment, the first nitride-based semiconductor layer is formed using MOCVD in an MOCVD reaction chamber.

In this embodiment, method 120 includes a step 122 of forming a pseudomorphic protective layer on the first nitride-based semiconductor layer. The pseudomorphic protective layer is generally formed using the same growth technique as that used to form the first nitride-based semiconductor layer. In accordance with the invention, the material included in the protective layer is more thermally and chemically stable so that the protective layer protects the first nitride-based semiconductor layer from having its material quality degraded in response to being exposed to heat and chemicals.

Further, in accordance with the invention, the pseudomorphic protective layer has a thickness less than a critical thickness. The thickness of the pseudomorphic protective layer is less than the critical thickness so that desired crystal properties are driven to match those of the first nitride-based semiconductor layer.

It should be noted that the pseudomorphic protective layer can be provided to the user with the substrate and first nitride-based semiconductor layer. When the pseudomorphic protective layer is provided to the user with the substrate and first nitride-based semiconductor layer, the pseudomorphic protective layer and first nitride-based semiconductor layer are typically formed in-situ, wherein they are formed in the same reaction chamber. For example, the pseudomorphic protective layer and first nitride-based semiconductor layer can be formed in-situ in the same MOCVD reaction chamber by using MOCVD.

In other embodiments, the pseudomorphic protective layer is formed on the first nitride-based semiconductor layer by the user. When the pseudomorphic protective layer is formed by the user on the first nitride-based semiconductor layer, the pseudomorphic protective layer and first nitride-based semiconductor layer are typically formed ex-situ, wherein they are formed in different reaction chambers. For example, the pseudomorphic protective layer and first nitride-based semiconductor layer can be formed ex-situ in different MOCVD reaction chambers by using MOCVD.

In this embodiment, method 120 includes a step 123 of forming a second nitride-based semiconductor layer on the pseudomorphic protective layer. The second nitride-based semiconductor layer can be formed using many different growth techniques. However, the growth technique used to form the first nitride-based semiconductor layer is chosen so that the second nitride-based semiconductor layer is formed at a faster growth rate than the first nitride-based semiconductor layer and protective layer. In this embodiment, HVPE is the growth technique used to form the second nitride-based semiconductor layer because HVPE provides faster growth rates than those provided by MOCVD. Hence, in this embodiment, the growth techniques used to form the first and second nitride-based semiconductor layers are different. However, it should be appreciated that, in other embodiments, the second nitride layer can also be formed using MOCVD, or a deposition technique other than HVPE, if desired.

In accordance with the invention, the material included in the second nitride-based semiconductor layer is formed with a low defect density by choosing desired crystal properties to correspond with those of the pseudomorphic protective layer. In one embodiment, the materials included in the protective layer and second nitride-based semiconductor layer have matching lattice structures. Further, in one embodiment, the in-plane lattice constants of the materials included in the protective layer and second nitride-based semiconductor layer correspond with each other. The defect density of the second nitride-based semiconductor layer is driven to a lower value when it has a matching lattice structure and the same or similar lattice constants as the protective layer because it includes fewer defects, such as dislocations. In this way, the second nitride-based semiconductor layer is formed at a faster rate and with a lower defect density.

The thickness of the second nitride-based semiconductor layer can have many different values relative to the thicknesses of the first nitride-based semiconductor layer, pseudomorphic layer, and template substrate. In this embodiment, the thickness of the second nitride-based semiconductor layer is driven to be greater than the thickness of the pseudomorphic protective layer. In some embodiments, the thickness of the second nitride-based semiconductor layer is driven to be greater than the thickness of the first nitride-based semiconductor layer. In some embodiments, the thickness of the second nitride-based semiconductor layer is driven to be greater than the thickness of the template substrate 101. The thickness of the second nitride-based semiconductor layer can be driven to be greater in many different ways, such as by including more material with it so its thickness increases.

It should be noted that the second nitride-based semiconductor layer is typically processed to form one or more solid-state devices therewith. Hence, in some embodiments, method 120 includes a step of processing the second nitride-based semiconductor layer to form one or more solid-state devices. The second nitride-based semiconductor layer can be processed in many different ways to form the solid-state device(s). For example, the processing generally involves photolithography and etching steps, as well as the formation of metallization.

FIG. 4 is a flow diagram of a method 125 of fabricating a semiconductor structure, in accordance with the invention. In this embodiment, method 125 includes a step 126 of providing a support structure which carries a first nitride-based semiconductor layer. It should be noted that the support structure and first nitride-based semiconductor layer form a composite substrate. It should also be noted that the support structure and first nitride-based semiconductor layer can be provided to the user or the first nitride-based semiconductor layer can be formed on the support structure by the user.

In this embodiment, method 125 includes a step 127 of forming a pseudomorphic protective layer on the first nitride-based semiconductor layer. In accordance with the invention, the pseudomorphic protective layer has a thickness which is less than a critical thickness. In one embodiment, the pseudomorphic protective layer has a thickness between about twenty angstroms to sixty angstroms. The thickness of the pseudomorphic layer is dependent on the materials comprising layers 104 and 105 and it should be appreciated that the thickness of the pseudomorphic layer will therefore change according to the choice of these materials. The materials included in the pseudomorphic protective layer and first nitride-based semiconductor layer generally have corresponding crystal properties, such as matching lattice structures and lattice constants. For example, the pseudomorphic protective layer and first nitride-based semiconductor layer generally have the same or similar in-plane lattice constants to reduce the number of dislocations generated.

In this embodiment, method 125 includes a step 128 of forming a second nitride-based semiconductor layer on the protective layer. More information regarding the formation of the second nitride-based semiconductor layer is provided above.

It should be noted that method 125 can include the same or similar steps as those included method 120. For example, the first nitride-based semiconductor layer and protective layer are typically formed in an MOCVD reactor by using MOCVD and the second nitride-based semiconductor layer is typically formed in an HVPE reactor by using HVPE. Further, it should be noted that the steps of methods 120 and 125 can be implemented in many different orders, and the order discussed herein is for illustrative purposes.

While particular embodiments of the invention have been shown and described, numerous variations and alternate embodiments will occur to those skilled in the art. Accordingly, it is intended that the invention be limited only in terms of the appended claims.

1. A semiconductor structure, comprising:
a substrate which includes a first nitride-based semiconductor layer;
a pseudomorphic protective layer formed on the first nitride-based semiconductor layer, the pseudomorphic protective layer having a thickness that is less than a critical thickness; and
a second nitride-based semiconductor layer formed on the pseudomorphic protective layer.

2. The structure of claim 1, wherein the critical thickness of the pseudomorphic protective layer is adjustable by adjusting the composition of the material included therein.

3. The structure of claim 1, wherein the pseudomorphic protective layer is a blanket layer of material.

4. The structure of claim 3, wherein the thickness of the second nitride-based semiconductor layer is greater than the thickness of the pseudomorphic protective layer.

5. The structure of claim 1, wherein the pseudomorphic protective layer includes at least one of aluminum nitride, aluminum gallium nitride, boron nitride, boron carbide, silicon carbide, zinc oxide and tantalum nitride.

6. The structure of claim 1, wherein the pseudomorphic protective layer includes a semiconductor material that is more thermally and chemically stable than the material included in the first nitride-based semiconductor layer.

7. The structure of claim 1, wherein the crystal properties of the pseudomorphic protective layer are driven to correspond with those of the first nitride-based semiconductor layer.

8. A semiconductor structure, comprising:
a substrate which includes a first nitride-based semiconductor layer;
a pseudomorphic protective layer formed on the first nitride-based semiconductor layer, wherein the thickness of the pseudomorphic protective layer is chosen so that its material quality is driven to correspond with that of the first nitride-based semiconductor layer; and
a second nitride-based semiconductor layer formed on the pseudomorphic protective layer, wherein the pseudomorphic protective layer drives the material quality of the second nitride-based semiconductor layer to correspond with that of the first nitride-based semiconductor layer.

9. The structure of claim 8, wherein the thickness of the pseudomorphic protective layer is chosen to restrict the amount the material included therein which is strain relaxed.

10. The structure of claim 8, wherein the pseudomorphic protective layer and second nitride-based semiconductor layer are blanket, layers of material.

11. The structure of claim 10, wherein the thickness of the second nitride-based semiconductor layer is greater than the thickness of the pseudomorphic protective layer.

12. The structure of claim 10, wherein the thickness of the second nitride-based semiconductor layer is driven to be greater than the first nitride-based semiconductor layer.

13. The structure of claim 8, wherein the first and second nitride-based semiconductor layers are formed using different growth techniques.

14. The structure of claim 8, wherein the first nitride-based semiconductor layer and pseudomorphic protective layer are formed in-situ, and the second nitride-based semiconductor layer is formed ex-situ.

15. A method of fabricating a semiconductor structure, comprising:
providing a support structure which carries a first nitride-based semiconductor layer;
forming a pseudomorphic protective layer on the first nitride-based semiconductor layer, wherein the pseudomorphic protective layer has a thickness which is less than a critical thickness; and
forming a second nitride-based semiconductor layer on the pseudomorphic protective layer, wherein the pseudomorphic protective layer drives the material quality of the second nitride-based semiconductor layer to correspond with that of the first nitride-based semiconductor layer.

16. The method of claim 15, wherein the step of forming the first and second nitride-based semiconductor layers includes forming them using different growth techniques.

17. The method of claim 15, wherein the pseudomorphic protective layer includes a semiconductor material that is more thermally and chemically stable than the material included in the first nitride-based semiconductor layer.

18. The method of claim 15, wherein the pseudomorphic protective layer and second nitride-based semiconductor layer are formed as blanket layers.

19. The method of claim 18, further including forming the second nitride-based semiconductor layer so its thickness is driven to be greater than the first nitride-based semiconductor layer.

20. The method of claim 18, further including forming the second nitride-based semiconductor layer so its thickness is driven to be greater than the pseudomorphic protective layer.
